(19) United States
(12) Patent Application Publication
(10) Pub. No.: US 2011/0041905 A1
(43) Pub. Date: Feb. 24, 2011

(54) ORGANIC SOLAR CELL AND METHOD FOR FORMING THE SAME

(75) Inventors: Feng-Yu Tsai, Taipei (TW); Ching Lin, Taipei (TW); En-Yung Lin, Taipei (TW)

Correspondence Address: PAI PATENT & TRADEMARK LAW FIRM, 1001 FOURTH AVENUE, SUITE 3200, SEATTLE, WA, 98154, US

(73) Assignee: NATIONAL TAIWAN UNIVERSITY, Taipei (TW)

(21) Appl. No.: 12/604,634

(22) Filed: Oct. 23, 2009

(30) Foreign Application Priority Data
Aug. 20, 2009 (TW) 098128013

(51) Int. Cl. H01L 51/46; H01L 31/00; H01L 51/48

(52) U.S. Cl. 136/256; 136/263; 438/82; 257/E51.026; 977/773

(57) ABSTRACT

The invention provides an organic solar cell, containing a substrate having a first electrode formed thereon, an organic photoactive layer including a crystalline, first organic molecule of a first conductive type and a second molecule of a second conductive type opposite to the first conductive type; and a second electrode overlying the organic photoactive layer. The invention further provides a method for forming the organic solar cell.

### CROSS REFERENCE TO RELATED APPLICATIONS

This application claims priority of Taiwan Patent Application No. 098128013, filed on Aug. 20, 2009, the entirety of which is incorporated by reference herein.

### BACKGROUND OF THE INVENTION

1. Field of the Invention

The present invention relates to an organic solar cell, and in particular relates to an organic solar cell having a photoactive layer of an optimized molecular morphology.

2. Description of the Related Art

In general, the lifetime of organic solar cells is shorter than silicon solar cells because of the morphological instability of the organic photoactive layer of organic solar cells. Also, the morphological instability of the organic photoactive layer also leads to low power conversion efficiency and inefficient power usage of organic solar cells. Here, morphology means a spatial distribution between p-type molecules and n-type molecules in the organic photoactive layer. The p-type molecules and n-type molecules are used for transporting holes and electrons, respectively. An ideal morphology contains two characteristics described as follows: (1) The largest contact area interface between the p-type and n-type molecules is referred to as the heterojunction. At the heterojunction, light converts to current (including electron current and hole current). Thus, a larger heterojunction may result in a higher light-to-energy conversion efficiency. (2) The largest continuous phase is formed by connecting the same conductive type of molecules, such as p-type or n-type molecules. Hole current and electron current are transported by the p-type and n-type continuous phases, respectively. Thus, a larger continuous phase may result in a higher light-to-energy conversion efficiency.

However, to achieve the first characteristic, n-type and p-type molecules require uniform mixing and contrarily, non-uniform mixing is required to achieve the second characteristics. Therefore, in order to form a more efficient organic solar cell, both characteristics must be achieved. Thus, methods have been disclosed, wherein a better light-to-energy conversion efficiency is achieved through optimization of the morphology of the organic photoactive layer. However, there are two problems which occur when optimizing the morphology of an organic photoactive layer: (1) Tuning the morphology of an organic photoactive layer to an optimized state is difficult; (2) Marinating the optimized state of the morphology of an organic photoactive layer for a long period of time is difficult, as the molecules in the organic photoactive layer are highly movable.

U.S. Pat. No. 6,670,213 and U.S. Pat. No. 6,312,971 disclose methods for rearranging molecules in an organic photoactive layer by thermal annealing and solvent annealing, respectively. High temperature or solvent makes the molecules in the organic photoactive layer highly movable such that the disordered molecules may be rearranged and tuned to improve the morphology thereof. Thus, the first problem described above can be resolved by these methods. However, excessive aggregations of the same type of molecules easily occur due to the high mobility of the molecules, thereby decreasing the area of the heterojunction. Furthermore, these methods fail to prevent the morphology from deforming over a long period of time. Thus, organic solar cells formed by these methods are instable.

U.S. Pat. No. 7,329,709 discloses a method, wherein cross-linkable molecules are used to form an organic photoactive layer. For example, fullerene having functional groups to cross link molecules in the organic photoactive layer by covalent boding is used. The morphology thus formed is stable over long periods of time. Thus, the second problem described above can be resolved by this method. However, currently, there is no suitable cross-link molecule which can efficiently absorb light for forming the organic photoactive layer. Thus, light-to-energy conversion efficiency of organic solar cells formed by this method is low.

### BRIEF SUMMARY OF THE INVENTION

One objective of the present invention is to provide an organic solar cell, comprising a substrate having a first electrode formed thereon, and an organic photoactive layer overlying the first electrode. The organic photoactive layer includes a crystalline first organic molecule of a first conductive type, and a second molecule of a second conductive type opposite to the first conductive type. A second electrode overlies the organic photoactive layer.

Still another objective of the present invention is to provide a method for forming an organic solar cell, comprising: providing a substrate with a first electrode formed thereon; coating a first organic molecule and a second molecule onto the first electrode to form a wet film, wherein the first organic molecule has a first conductive type and the second molecule has a second conductive type opposite to the first conducive type; placing the wet film at a first temperature such that a crystal nucleus from the first organic molecule is formed, and drying the wet film to form a dry film; placing the dry film at a second temperature for crystal growth, to form an organic photoactive layer including the first organic molecule of a crystalline phase and the second molecule; and forming a second electrode on the organic photoactive layer.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1 through 6 are section views of one embodiment of an organic solar cell at various fabrication stages constructed according to aspects of the present disclosure.

FIG. 7 illustrates a comparison of an X-ray diffraction scheme of Example 1 according to the present disclosure and Comparative Example 1.

FIG. 8 illustrates a comparison of currents versus voltages of Example 1 according to the present disclosure and Comparative Example 1.

FIG. 9 illustrates a comparison of light-to-energy conversion efficiency versus lifetime at 65° C. of Example 1 according to the present disclosure and Comparative Example 1.

### DETAILED DESCRIPTION OF THE INVENTION

The following description is of the best-contemplated mode of carrying out the invention. It is understood that the following disclosure provides many different embodiments, or examples, for implementing different features of the invention. Specific examples of components and arrangements are described below to simplify the present disclosure. These are, of course, merely examples and are not intended to be limiting. For example, the formation of a first feature over, above, below, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. The scope of the invention is best determined by reference to the appended claims.

The method disclosed herein provides steps for forming an organic photoactive layer. A large quantity of crystal nuclei are formed at a low temperature and then crystal growth is performed rapidly at a high temperature for forming large quantities of high crystalline molecules. The high crystalline molecules are further densely connected to each other to form a crystalline network. The crystalline network does not only provide a large heterojunction which is advantageous to increase photoelectric conversion, but also provides a continuous phase for transporting currents. Thus, the light-to-energy conversion efficiency of the organic solar cell can be improved. Furthermore, migration of non-crystalline molecules in the organic photoactive layer is limited. Morphology of the organic photoactive layer is maintained such that the lifetime of the organic solar cell is extended.

The method disclosed herein provides an organic solar cell device, at least including a substrate, a first electrode, an organic photoactive layer and a second electrode. The organic photoactive layer includes molecules having two different conductive types opposite to each other and at least one of the molecules is a crystalline organic molecule. Moreover, the organic solar cell further comprises a hole transporting layer interposed between the first electrode and the organic photoactive layer, for improving the injection and transport of holes.

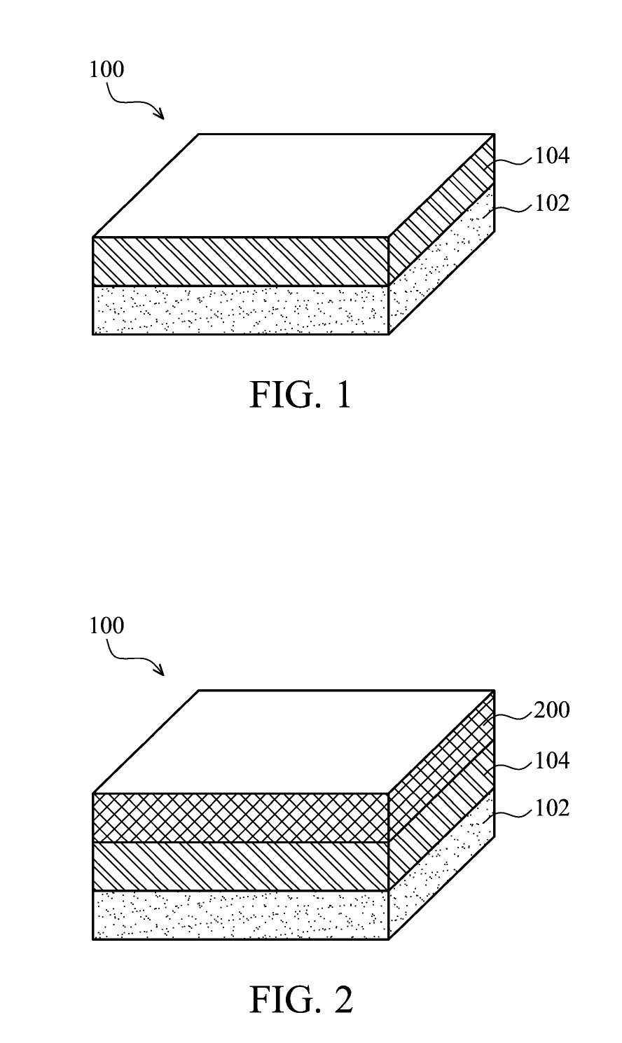

In one embodiment according to the invention, referring to FIG. 1, which provides a method 100 for forming an organic solar cell, at first, a substrate 102 is provided. The substrate 102 includes hard material, flexible material, transparent material or semi-transparent material. For example, the substrate 102 is a glass substrate or a transparent plastic substrate. A first electrode 104 is formed on the substrate 102. The first electrode 104 may be a transparent conductive layer including tin dioxide, zinc oxide, indium tin oxide, indium zinc oxide, antimony doped tin dioxide (ATO), fluorine doped tin dioxide (FTO), and aluminum doped zinc (AZO) or a combination thereof. In addition, in the present embodiment, the first electrode 104 is an anode.

Referring to FIG. 2, in one embodiment, a hole transporting layer 200 is formed on the first electrode 104. The work function of the first electrode 104 is modified by the hole transporting layer 200 to reduce the hole injection barrier, thereby improving the hole transport efficiency. The hole transporting layer 200 also blocks electrons. Additionally, the formation of the hole transporting layer 200 helps to planarize the surface of the first electrode 102 to reduce the surface roughness of the substrate. The hole transporting layer 200 preferably comprises a transparent conductive polymer including 3,4-polyethylenedioxythiophene: polystyrene sulfonate (PEDOT:PSS), poly(2,7-(9,9-di-n-octylfluorene)-(1,4-.phenylene-(4-imino(benzoic acid))-1,4-phenylene-(4-imino (benzoic acid))-1,4-phenylene)) (BFA), polyaniline (PAN), polyphenylenevinylene (PPV) or combinations thereof. The hole transporting layer 200 may be formed by any suitable deposition methods, such as a spin-coating, doctor blade coating, roll coating, jet-ink printing, screen printing or other suitable methods. In the present embodiment, the hole transporting layer 200 is preferably formed of 3,4-polyethylenedioxythiophene:polystyrene sulfonate (PEDOT:PSS) having a work function higher than indium tin oxide about 0.5 eV. The hole transporting layer 200 has a thickness between about 10 and 9000 nm, preferably between about 20 and 100 nm.

Next, a solution containing a first organic molecule and a second molecule is prepared. Preferably, the first organic molecule has a first conductive type and the second molecule has a second conductive type opposite to the first conductive type, respectively. In one embodiment, if the first organic molecule is p-type, the second molecule is n-type. In another embodiment, if the first organic molecule is n-type, the second molecule is p-type. Additionally, the first organic molecule and the second molecule are capable of absorbing light and converting it to current. Additionally, the first organic molecule may be an organic molecule that crystallizes easily, such as poly(3-hexylthiophene), poly(3-butylthiophene), pentacene, pentacene derivatives, or combinations thereof. The second molecule may be an organic or inorganic molecule that crystallizes easily or does not crystallize easily, such as (6,6)-phenyl C61-butyric acid methyl ester, (6,6)-phenyl C71-butyric acid methyl ester, titanium dioxide nanoparticles, cadmium selenide nanoparticles or combinations thereof.

In one embodiment, a molar ratio of the first organic molecule to the second molecule is between about 1:0.1 and 1:10. In a preferable embodiment, a molar ratio of the first organic molecule to the second molecule is between about 1:0.5 and 1:2. The solution contains a solvent, which may be any solvent capable of dissolving both the first organic molecule and second molecule. For example, the solvent may be chloroform, dichloromethane, toluene, xylene, trimethylbenzene, chlorobenzene, dichlorobenzene, trichlororbenzene, methanol, ethanol, other suitable solvents or combinations thereof.

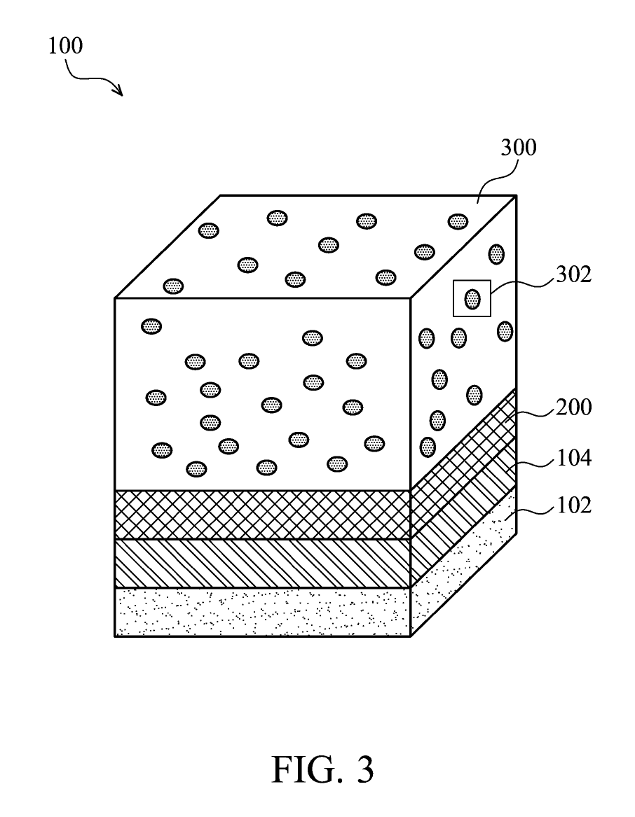

Referring to FIG. 3, the solution described above is deposited on the hole transporting layer 200 to form a wet film 300 by any suitable deposition methods, such as a spin-coating, doctor blade coating, roll coating, jet-ink printing, screen printing or other suitable methods, wherein the wet film 300 comprises the first organic molecule and a second molecule. In the wet film 300, the first organic molecule and the second molecule are presented in a non-crystalline mixtures 302 form. Notice that a portion of the solvent still remain in the wet film.

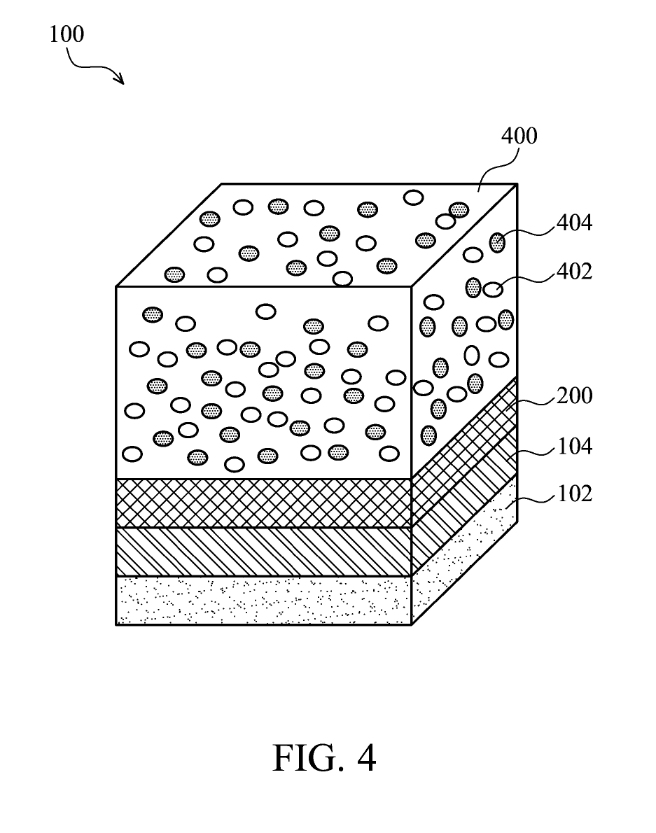

Referring to FIG. 4, the organic solar cell 100 having the wet film 300 is placed at a first temperature such that a crystal nuclei 402 is formed from the first organic molecule. The first temperature is lower than a room temperature, such as between −20° C. and 10° C., preferably between −8° C. and 0° C. Because a portion of the solvent still remains in the wet film 300, a large quantity of crystal nuclei 402 are deposited from the first organic molecules 302 in the wet film 300 at a low temperature environment. Then, the wet film 300 is dried to a dry film 400. In one embodiment, the wet film 300 may be placed at a first temperature for a sufficient time until the wet film 300 is completely dried. It should be noted that at this time, all of the solvent have been already removed from the dry film 400.

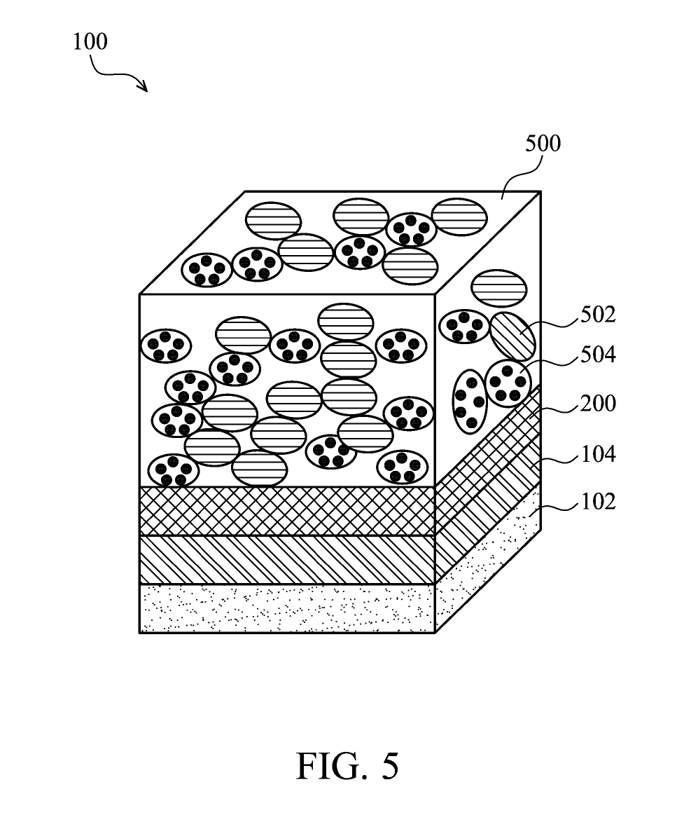

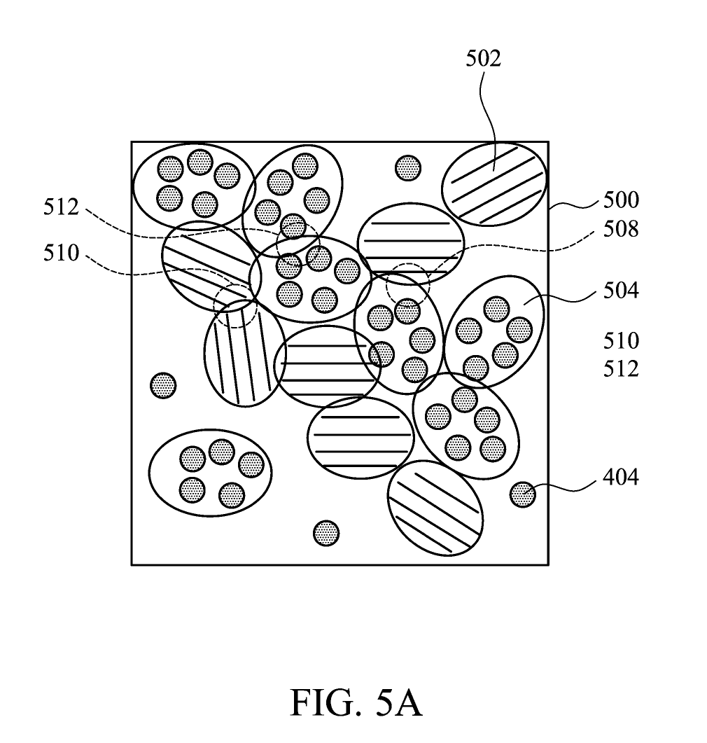

Referring to FIG. 5, the organic solar cell 100 having the dry film 400 is placed at a second temperature for crystal growth, to form an organic photoactive layer 500 from the dry film 400. The second temperature is higher than a room temperature, such as between 40° C. and 400° C., preferably between 110° C. and 200° C. At the second temperature, the crystal nuclei 402 of the first organic molecule are connected to each other to form a crystalline first organic molecule 502. In addition, the second molecule 404 may be fixed and distributed uniformly in the remaining spaces of the organic photoactive layer 500 due to constraint of the crystalline first organic molecule 502. Alternatively, little aggregation 504 may be formed from the second molecule 404, as shown in FIG. 5. It should be noted that since the crystal nuclei 402 of the first organic molecule has been formed at a low temperature (e.g. at the first temperature), the crystal nuclei 402 of the first organic molecule rapidly grows to high crystalline molecules while the dry film 400 is placed at the second temperature, and most of the remaining non-crystalline first organic molecules are completely depleted while forming a dense crystalline network.

Referring to FIG. 5A, which shows a detailed view of the organic photoactive layer 500 of FIG. 5. A dense crystalline network is formed of the crystalline first organic molecules 502. There is almost no non-crystalline first organic molecule in the organic photoactive layer 500. Furthermore, the molecules are constrained by the crystalline network in the organic photoactive layer 500 such that the migration of the molecules limited and excessive aggregations are eliminated. The organic photoactive layer 500 provides a large hetreojunction 508 and continuous crystalline phases 510, 512 formed of the first organic molecule and the second molecule, respectively (e.g. n-type and p-type continuous phase, respectively). The continuous phases 510, 512 provide for transporting current. Accordingly, a large area for light converting to energy and high efficiency of the transporting currents may be provided concurrently by the organic photoactive layer 500. In addition, no molecule will easily migrate in the organic photoactive layer 500 such that the morphology of the organic photoactive layer is maintained without deformation over a long time period.

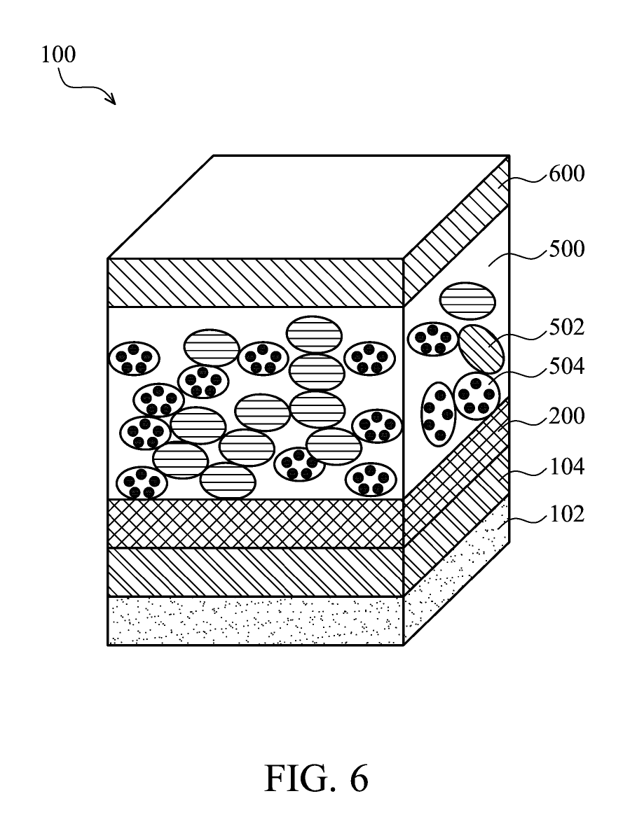

Referring to FIG. 6, a second electrode is formed on the organic photoactive layer 500 to form a full organic solar cell 100. The second electrode may comprise metals or alloys having a relative lower work function, such as aluminum, lithium, magnesium, calcium, indium, potassium, alloys thereof or combinations thereof. In one embodiment, the second electrode 600 may comprise multiple layers of different materials, such as aluminum/calcium, magnesium-/indium, indium/silver, magnesium/lithium, aluminum/silver, aluminum/lithium or combinations thereof. In the present embodiment, the second electrode 600 is formed of aluminum/calcium layers. The second electrode 600 is formed of aluminum/calcium layers performing as a cathode.

Finally, the organic solar cell is encapsulated to avoid oxygen and humidity to enter therein and reduce performance. Any impermeable substrates may be used to encapsulate the organic solar cell, such as glass, or metals. UV glues or resins may be used to encapsulate the sides between the organic solar cell and the impermeable substrate. Alternatively, a desiccant or oxygen absorbing agent may be added into the encapsulated organic solar cell to assure that the organic solar cell does not contain oxygen and humidity. Accordingly, the formed organic solar cell has a short circuit current between about 8 and 25 mA/cm² and a light-to-energy conversion efficiency of between about 3.5% and 15%.

The organic solar cell according to the present method comprises an organic photoactive layer having several advantages as follows: (1) Large quantities of crystal nuclei are formed. A large quantity of crystal nuclei are formed at a low temperature and the molecules adjacent to the crystal nuclei are rapidly depleted. Thus, compared to prior art, non-crystalline molecules are significantly reduced and excessive aggregations formed by the non-crystalline molecules are also eliminated, thereby increasing the heterojunction and improving the light-to-energy conversion efficiency; (2) Due to the formation of the dense crystalline network, current is transported more efficiently; (3) The morphology of the organic photoactive layer is very stable. The remaining non-crystalline does not migrate and aggregate because the non-crystalline molecules are depleted while forming the crystalline network. Also, the non-crystalline molecules are constrained by the crystalline network. Thus, a stable morphology of the organic photoactive layer results in a stable performance of the organic solar cell.

### Example 1

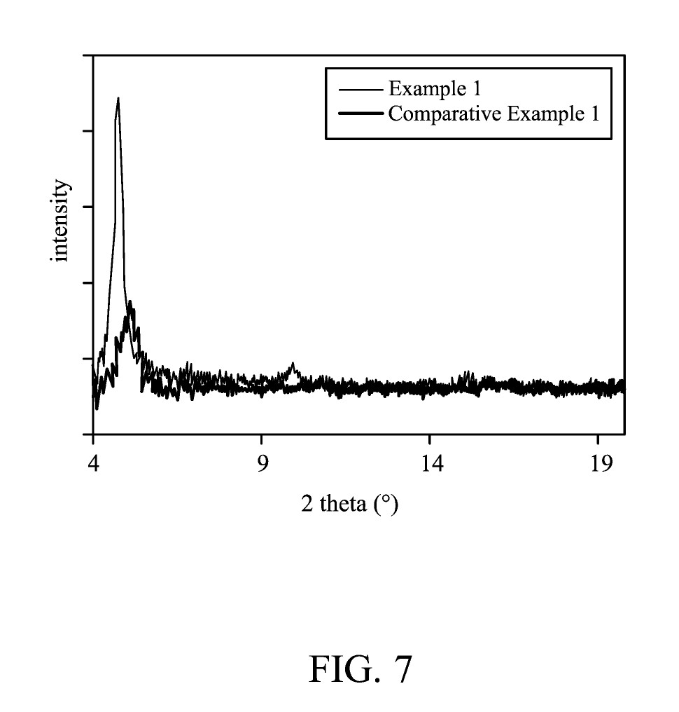

A mixed aqueous solution of 3,4-polyethylenedioxythiophene and polystyrene sulfonate (PEDOT:PSS) was prepared, wherein the mass ratio of PEDOT to PSS to water was 2:1:10. Next, the mixed aqueous solution was deposited by spin-coating onto a conductive glass having indium tin oxide formed thereon and dried for 20 minutes. The formed PEDOT:PSS layer had a thickness of about 50 nm. Then, another mixed solution of poly(3-hexylthiophene) and (6,6)-phenyl C61-butyric acid methyl ester (P3HT:PCBM) was prepared, wherein the mass ratio of P3HT to PCBM was 1:1. Here, P3HT served as a p-type molecule and PCBM served as an n-type molecule. At room temperature, the mixed solution of P3HT and PCBM was deposited onto the PEDOT:PSS layer by a spin-coating process. The formed P3HT:PCBM layer had a thickness of about 240 nm. Then, the wet P3HT:PCBM layer was placed at a temperature of −5° C. under 1 atm N₂ until the P3HT:PCBM layer was completely dried. Thereafter, the dried P3HT:PCBM layer was heated at a temperature of 190° C. for 2 minutes to form crystalline P3HT. Calcium/aluminum layers were deposited on the dried P3HT:PCBM layer by evaporation, which had a thickness of 10 and 100 nm, respectively. Finally, the device was encapsulated by glass and UV glues to form a full organic solar cell device. The formed organic solar cell had a fill factor of 66.5% and an open-circuit voltage of 0.61V. The characterizations of X-ray diffraction, photocurrent and light-to-energy conversion efficiency are shown in FIGS. 7-9.

### Comparative Example 1

The same procedure as in Example 1 was repeated for Comparative Example 1, except that the P3HT: PCBM layer was dried at a room temperature without heating at a temperature of 190° C. The formed full organic solar cell of Comparative Example 1 had a fill factor of 66.5% and an open-circuit voltage of 0.53V. The characterizations of X-ray diffraction, short-circuit current and power conversion efficiency are shown in FIGS. 7-9.

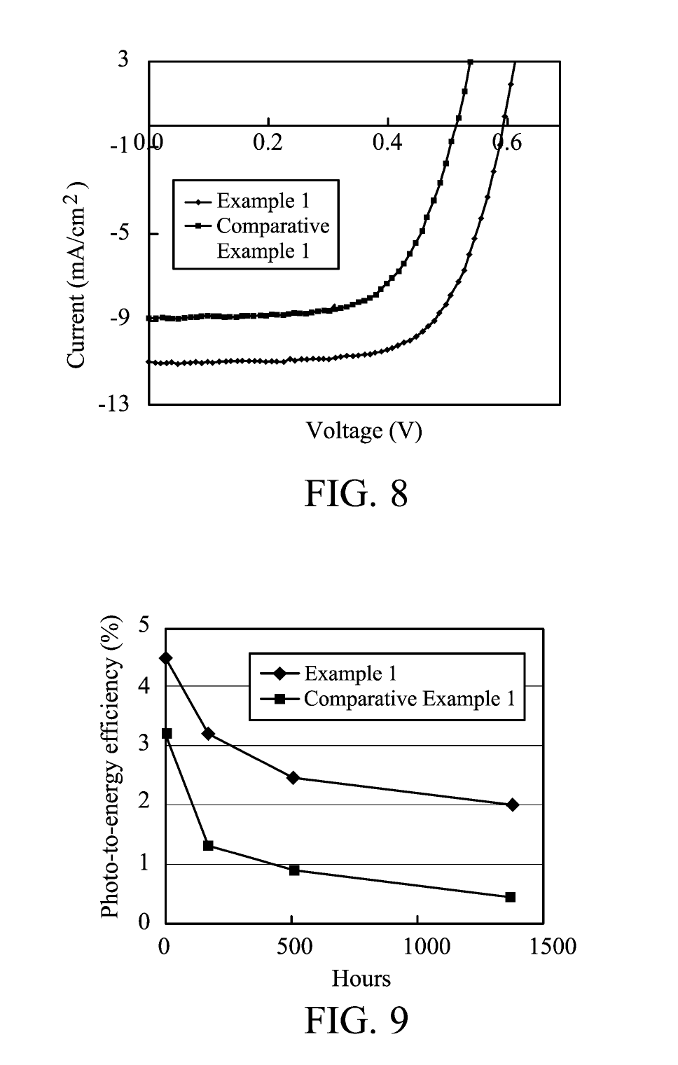

The XRD comparisons between Example 1 and Comparative Example 1 are shown in FIG. 7, which shows that the strength of the crystalline phase (100) of Example 1 was 6.3 times higher than Comparative Example 1. Thus, the first organic molecule has a continuous crystalline phase. Referring to FIG. 8, the short-circuit current of Example 1 was 11 mA/cm², and the short-circuit current was merely 9 mA/cm² in Comparative Example 1. Referring to FIG. 9, the initial light-to-energy conversion efficiency and the half-lifetime of the organic solar cell of Example 1 were 4.5% and 1092 hours, however, they were merely 3.2% and 143 hours in Comparative Example 1. Thus, the organic solar cell according to the invention had better light-to-energy conversion efficiency and longer half-lifetime. The lifetime of the organic solar cell according to the invention was 7.6 times longer than conventional organic solar cell.

In summary, the present invention provides a method for modifying the organic photoactive layer of the organic solar cell to make the organic photoactive layer have an ideal morphology. The method disclosed herein utilizes simple processes to form a high crystalline phase of the first organic molecule to maximize the heterojunction between the first organic molecule and the second molecule and respectively form the continuous phases of the first organic molecule and the second molecule. Furthermore, the optimized morphology of the organic photoactive layer is maintained. Therefore, the light-to-energy conversion efficiency and the stability of the organic solar cell are significantly improved when compared to the convention organic solar cell.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An organic solar cell, comprising
a substrate having a first electrode formed thereon;
an organic photoactive layer overlying the first electrode, wherein the organic photoactive layer includes:
a crystalline first organic molecule of a first conductive type; and
a second molecule of a second conductive type opposite to the first conductive type; and
a second electrode overlying the organic photoactive layer.

2. The organic solar cell as claimed in claim 1, wherein the substrate comprises a glass substrate, transparent plastic substrate or combinations thereof.

3. The organic solar cell as claimed in claim 1, wherein the first electrode comprises a transparent conductive layer including tin oxide, zinc oxide, indium tin oxide, indium zinc oxide, antimony tin oxide, fluorine doped tin oxide, aluminum doped zinc oxide or combinations thereof.

4. The organic solar cell as claimed in claim 1, further comprising a hole transporting layer disposed between the first electrode and the organic absorption layer.

5. The organic solar cell as claimed in claim 4, wherein the hole transporting layer comprises 3,4-polyethylenedioxythiophene: polystyrene sulfonate (PEDOT:PSS), poly(2,7 -(9,9-di-n-octylfluorene)-(1,4-.phenylene-(4-imino(benzoic acid))-1,4-phenylene-(4-imino (benzoic acid))-1,4-phenylene)) (BFA), polyaniline (PAN), polyphenylenevinylene (PPV) or combinations thereof.

6. The organic solar cell as claimed in claim 1, wherein the first organic molecule comprises poly(3-hexylthiophene), poly(3-butylthiophene), pentacene, pentacene derivatives or combinations thereof.

7. The organic solar cell as claimed in claim 1, wherein the second molecule comprises (6,6)-phenyl C61-butyric acid methyl ester, (6,6)-phenyl C71-butyric acid methyl ester, titanium dioxide nanoparticles, cadmium selenide nanoparticles or combinations thereof.

8. The organic solar cell as claimed in claim 1, wherein the first organic molecule is n-type while the second molecule is p-type.

9. The organic solar cell as claimed in claim 1, wherein the first organic molecule is p-type while the second molecule is n-type.

10. The organic solar cell as claimed in claim 1, wherein the second electrode comprises aluminum, lithium, magnesium, calcium, indium, potassium, alloys thereof or combinations thereof.

11. The organic solar cell as claimed in claim 1, wherein a mass ratio of the first organic molecule to the second molecule is between about 1:0.1 and 1:10.

12. The organic solar cell as claimed in claim 1, wherein the first organic molecule forms a crystalline network in the organic photoactive layer.

13. The organic solar cell as claimed in claim 1, wherein the organic photoactive layer has a thickness between about 10 and 9000 nm.

14. The organic solar cell as claimed in claim 1, wherein the organic solar cell has a short circuit current between about 8 and 25 mA/cm².

15. The organic solar cell as claimed in claim 1, wherein the organic solar cell has a power conversion efficiency between about 3.5% and 15%.

16. A method for forming organic solar cell, comprising:
providing a substrate with a first electrode formed thereon;
coating a first organic molecule and a second molecule onto the first electrode to form a wet film, wherein the first organic molecule has a first conductive type and the second molecule has a second conductive type opposite to the first conducive type;
placing the wet film at a first temperature such that a crystal nucleus from the first organic molecule is formed, and drying the wet film to form a dry film;
placing the dry film at a second temperature for crystal growth, to form an organic photoactive layer including the first organic molecule of a crystalline phase and the second molecule; and
forming a second electrode on the organic photoactive layer.

17. The method as claimed in claim 16, wherein the substrate comprises a glass substrate, transparent plastic substrate or combinations thereof.

18. The method as claimed in claim 16, wherein the first electrode comprises a transparent conductive layer, which includes tin oxide, zinc oxide, indium tin oxide, indium zinc oxide, antimony tin oxide, fluorine doped tin oxide, aluminum doped zinc oxide or combinations thereof.

19. The method as claimed in claim 16, further comprising a hole transporting layer disposed between the first electrode and the organic photoactive layer.

20. The method as claimed in claim 19, wherein the hole transporting layer comprises 3,4-polyethylenedioxythiophene: polystyrene sulfonate (PEDOT: PSS), poly(2,7-(9,9-di-n-octylfluorene)-(1,4-.phenylene-(4-imino(benzoic acid))-1,4-phenylene-(4-imino (benzoic acid))-1,4-phenylene)) (BFA), polyaniline (PAN), polyphenylenevinylene (PPV) or combinations thereof.

21. The method as claimed in claim 16, wherein the first organic molecule is n-type while the second molecule is p-type.

22. The method as claimed in claim 16, wherein the first organic molecule is p-type while the second molecule is n-type.

23. The method as claimed in claim 16, wherein the second electrode comprises aluminum, lithium, magnesium, calcium, indium, potassium, alloys thereof or combinations thereof.

24. The method as claimed in claim 16, wherein the first organic molecule comprises poly(3-hexylthiophene), poly(3-butylthiophene), pentacene, pentacene derivatives or combinations thereof.

25. The method as claimed in claim 16, wherein the second molecule comprises (6,6)-phenyl C61-butyric acid methyl ester, (6,6)-phenyl C71-butyric acid methyl ester, titanium dioxide nanoparticles, cadmium selenide nanoparticles or combinations thereof.

26. The method as claimed in claim 16, wherein a mass ratio of the first organic molecule to the second molecule is between about 1:0.1 and 1:10.

27. The method as claimed in claim 16, wherein the first organic molecule forms a crystalline network in the organic photoactive layer.

28. The method as claimed in claim 16, wherein the first temperature is between about −20 and 10° C.

29. The method as claimed in claim 16, wherein the second temperature is between about 40 and 400° C.
